(19) United States
(12) Patent Application Publication
(10) Pub. No.: US 2011/0083886 A1
(43) Pub. Date: Apr. 14, 2011

(54) METHOD OF MANUFACTURING ELECTRODE SUBSTRATE

(75) Inventor: Jeong Han KIM, Seongnam-shi (KR)

(73) Assignee: KOLON INDUSTRIES, INC., Gyeonggi-do (KR)

(21) Appl. No.: 12/898,225

(22) Filed: Oct. 5, 2010

(30) Foreign Application Priority Data
Oct. 6, 2009 (KR) 10-2009-0094644

(51) Int. Cl. H05K 1/09; B05D 5/12

(52) U.S. Cl. 174/257; 427/122; 977/750; 977/752; 977/932

(57) ABSTRACT

Disclosed herein is a method of manufacturing an electrode substrate, by which a film-shape electrode substrate including a carbon nanotube layer, which does not include a dispersant, is not related to the kind of binder and is strongly attached to the electrode substrate, can be easily manufactured.

### BACKGROUND OF THE INVENTION

1. Technical Field

The present invention relates to a method of manufacturing an electrode substrate, and, more particularly, to a method of manufacturing an electrode substrate including a carbon nanotube layer on the surface of the polymer resin film.

2. Description of the Related Art

As computers, electric appliances, communication devices and the like are rapidly digitalized and highly advanced, it is keenly required to realize portable large-area displays. In order to realize portable large-area flexible displays, display materials having foldable and rollable properties, like those of a newspaper, are needed.

For this purpose, electrode materials for displays must be transparent and have low resistance, and must have high strength such that display devices are mechanically stable even when they are warped or folded. Further, electrode materials for displays must have a thermal expansion coefficient similar to that of a plastic substrate such that display devices do not short out or their surface resistances do not greatly change even when they overheat or their temperatures become high.

Since flexible display materials can be used to manufacture displays of various shapes, they can also be used in trademarks of color-pattern-changeable clothes, advertising boards, price signboards of goods display stands, large-area electric illuminators and the like as well as portable display devices.

In relation to this, a transparent conductive thin film is a flexible display material that is widely used in devices requiring both transparency and conductivity, such as image sensors, solar cells, and various kinds of displays (PDPs, LCDs, flexible displays).

Generally, research has been widely conducted into using indium tin oxide (ITO) to prepare transparent electrodes for flexible displays. However, an ITO thin film is problematic in that processing expenses are increased because a vacuum process is required in order to prepare the ITO film, and in that its life span is shortened because it is broken when a display device is warped or folded.

In order to solve the above problems, Korean Unexamined Patent Application Publication No. 10-2005-001589 discloses a transparent electrode having a transmissivity of 80% or more and a surface resistance of 100 Ω/sq or less in a visible light range, which can minimize the scattering of light and has improved conductivity, prepared by chemically bonding carbon nanotubes with a polymer to form a film or by coating a conductive polymer layer with refined carbon nanotubes or carbon nanotubes chemically bonded with a polymer to disperse the carbon nanotubes in or on the coated conductive polymer layer on the nanoscale and then introducing metal nanoparticles, such as gold nanoparticles or silver nanoparticles, into the coated conductive polymer layer. Here, concretely, the transparent electrode is manufactured by reacting a carbon nanotube-dispersed solution with polyethylene terephthalate (PET) to form a high-concentration carbon nanotube-polymer copolymer solution, applying the carbon nanotube-polymer copolymer solution onto a polyester film, and then drying the polyester film coated with the copolymer solution.

As such, when a film-shape substrate is manufactured using carbon nanotubes, an additional substrate is needed, and a PET substrate is chiefly used as a transparent substrate.

Hence, a binder and a dispersant are additionally required in order to form a carbon nanotube layer, and the binder and dispersant are different from each other in the properties of dispersing carbon nanotubes depending on the kinds thereof, so that proper dispersion conditions, such as the selection of the dispersant and the like, must be ensured depending on the kind of polymer resin used as the binder.

### SUMMARY OF THE INVENTION

Accordingly, the present invention has been devised to solve the above-mentioned problems, and the present invention intends to provide a method of manufacturing an electrode substrate, wherein a carbon nanotube layer of the finally-obtained electrode substrate does not include a dispersant, and all kinds of soluble polymer resin binders can be used.

Further, the present invention intends to provide a method of manufacturing an electrode substrate including a polymer resin strongly bonded with carbon nanotubes.

An aspect of the present invention provides a method of manufacturing an electrode substrate, including the steps of: applying a carbon nanotube-dispersed solution containing a low-molecular-weight dispersant onto a polymer substrate to form a the carbon nanotube-dispersant mixing layer; washing the carbon nanotube-dispersant mixing layer to remove the low-molecular-weight dispersant; impregnating the polymer substrate including the carbon nanotube-dispersant mixing layer from which the low-molecular-weight dispersant was removed with a polymer resin solution; and taking out the polymer substrate from the polymer resin solution and then drying the polymer substrate.

In the method, the low-molecular-weight dispersant may include one or more selected from sodium dodecyl sulfate, lithium dodecyl sulfate, sodium dodecyl benzenesulfonate, sodium dodecyl sulfonate, dodecyltrimethylammonium bromide, and cetyltrimethylammonium bromide.

Further, the carbon nanotube may be selected from single-wall carbon nanotubes, double-wall carbon nanotubes, and multi-wall carbon nanotubes.

Further, the polymer substrate may be made of any one selected from polyimide, polyether sulfone, polyether ether ketone, polyethylene terephthalate, polybutylene terephthalate, polycarbonate, polyacrylate, and polyurethane.

Further, in the step of forming the carbon nanotube-dispersant mixing layer on the polymer substrate, the polymer substrate may be coated with the carbon nanotube-dispersed solution containing the low-molecular-weight dispersant while it is heated to 60˜100° C.

Further, the polymer resin constituting the polymer resin solution for impregnating the polymer substrate may be selected from polyimide, polyether sulfone, polyether ether ketone, polyethylene terephthalate, polybutylene terephthalate, polycarbonate, polyacrylate, polyvinyl pyrrolidone, epoxy, and polyurethane.

Further, the polymer resin constituting the polymer resin solution for impregnating the polymer substrate may be a photocurable resin or a thermocurable resin.

Further, the polymer resin solution for impregnating the polymer substrate may include at least one solvent selected from water, alcohol, acetone, ether, acetate, and toluene.

Further, the polymer resin solution for impregnating the polymer substrate may have a solid content of 0.01˜5 wt %.

Further, the step of drying the polymer substrate may be performed at a temperature of 10˜400° C. for 1 minutes ˜3 hours.

Further, the step of drying the polymer substrate may be performed such that a film formed on the polymer substrate by the polymer resin solution after the drying has a thickness of 0.001˜0.1 μm from the top of the polymer substrate. The method may further include the step of: curing the dried polymer substrate after the step of drying the polymer substrate.

Another aspect of the present invention provides an electrode substrate manufactured by the above method, wherein the electrode substrate is formed of a polymer resin substrate including a carbon nanotube-polymer resin mixing layer containing no dispersant thereon.

### DESCRIPTION OF THE PREFERRED EMBODIMENTS

Hereinafter, preferred embodiments of the present invention will be described in detail with reference to the attached drawings.

An embodiment of the present invention provides a method of manufacturing an electrode substrate, including the steps of: applying a carbon nanotube-dispersed solution containing a low-molecular-weight dispersant onto a polymer substrate to form a carbon nanotube-dispersant mixing layer; washing the carbon nanotube-dispersant mixing layer to remove the low-molecular-weight dispersant; impregnating the polymer substrate including the carbon nanotube-dispersant mixing layer from which the low-molecular-weight dispersant was removed with a polymer resin solution; and taking out the polymer substrate from the polymer resin solution and then drying the polymer substrate.

According to an embodiment of the present invention, the preparation of the carbon nanotube-dispersed solution is not particularly limited. However, for example, the carbon nanotube-dispersed solution may be prepared by mixing carbon nanotubes in an aqueous low-molecular-weight dispersant solution, dispersing the carbon nanotubes in the aqueous low-molecular-weight dispersant solution using a sonicator to form a carbon nanotube-dispersed solution and then separating the agglomerated carbon nanotubes from the carbon nanotube-dispersed solution using a centrifugal separator.

In this case, examples of the low-molecular-weight dispersant may include cationic surfactants, such as sodium dodecyl sulfate, lithium dodecyl sulfate, sodium dodecyl benzenesulfonate, sodium dodecyl sulfonate, dodecyltrimethylammonium bromide, cetyltrimethylammonium bromide, an the like.

Examples of the carbon nanotubes may include, but are not limited to, single-wall carbon nanotubes, double-wall carbon nanotubes, multi-wall carbon nanotubes, and the like.

Water is used as a solvent for dispersing the carbon nanotubes and the low-molecular-weight dispersant.

The amount of the carbon nanotubes in the obtained carbon nanotube-dispersed solution may be 0.0001˜0.2 wt %, which is advantageous in terms of the transmissivity of an electrode substrate after coating.

The obtained carbon nanotube-dispersed solution is applied onto a polymer substrate. In this case, the polymer substrate may be coated with the carbon nanotube-dispersed solution by spray coating while it is heated to 60° C. or more, preferably, 60˜100° C. This coating process is advantageous in that the spray rate of the carbon nanotube-dispersed solution is increased, and the carbon nanotube-dispersed solution applied on the polymer substrate is rapidly dried, so that it is possible to prevent the carbon nanotube-dispersed solution dispersed on the polymer substrate from agglomerating, thereby not causing the problem of transmissivity deterioration.

According to an embodiment of the present invention, in consideration of heat resistance and solubility, the polymer substrate may be made of any one selected from polyimide, polyether sulfone, polyether ether ketone, polyethylene terephthalate, polybutylene terephthalate, polycarbonate, polyacrylate, and polyurethane.

Subsequently, the polymer substrate coated with carbon nanotubes is immersed in water for 10 minutes or more to remove the low-molecular-weight dispersant therefrom.

In this way, a carbon nanotube layer, from which the low-molecular-weight dispersant has been removed, is formed on the polymer substrate, and this polymer substrate, on which the carbon nanotube-dispersant mixing layer is formed, is impregnated with a polymer resin solution.

According to an embodiment of the present invention, in consideration of heat resistance and solubility of the polymer substrate, the polymer resin constituting the polymer resin solution for impregnating the polymer substrate may be selected from polyimide, polyether sulfone, polyether ether ketone, polyethylene terephthalate, polybutylene terephthalate, polycarbonate, polyacrylate, polyvinyl pyrrolidone, epoxy, and polyurethane.

Further, the polymer resin constituting the polymer resin solution for impregnating the polymer substrate may be a photocurable resin or a thermocurable resin, which can form a film when treated with an additional curing process.

According to an embodiment of the present invention, the solvent used to prepare the polymer resin solution may be selected from water, alcohol, acetone, ether, acetate, toluene and mixtures thereof. Any solvent may be used as the solvent as long as it can dissolve the polymer resin.

The polymer resin solution may have a solid content of 0.01˜5 wt %, which is advantageous in terms of surface resistance.

Subsequently, the impregnated polymer substrate is taken out from the polymer resin solution, and then dried. In this case, drying conditions may be changed in consideration of the heat resistance of the polymer substrate and the polymer resin that is used. Preferably, the drying of the polymer substrate may be performed at a temperature of 10˜400° C. for 1 minutes ˜3 hours to form a polymer resin film.

When the polymer resin solution includes a curable polymer resin, considering the curing conditions of the curable polymer resin used after the drying process, a curing process may further be performed.

The thickness of the polymer resin film formed by the polymer resin solution may be 0.001˜0.1 μm from the top of the polymer substrate, considering that, in terms of minimizing the decrease in electroconductivity of the carbon nanotube-polymer resin mixing layer, the polymer resin film is advantageous as it is thin, but that the adhesivity of the carbon nanotube-polymer resin mixing layer is decreased when it is excessively thin.

The polymer resin film formed in this way is not separated from the carbon nanotube layer, which is formed by removing the dispersant from the carbon nanotube-dispersant mixing layer, but is integrated with the carbon nanotube-polymer resin mixing layer in the form of a polymer resin bonded with the carbon nanotubes of the carbon nanotube layer such that the polymer resin film and the carbon nanotube layer strongly adhere to each other.

The resulting product is a polymer resin substrate including a carbon nanotube-polymer resin mixing layer containing no dispersant thereon, and the polymer resin substrate is a useful electrode substrate.

Hereinafter, the present invention will be described in more detail with reference to the following Examples. However, the scope of the present invention is not limited thereto.

### Example 1

Carbon nanotubes (single-wall carbon nanotubes, manufactured by Nanosolution Corp.) were mixed in an aqueous solution containing 1 wt % of sodium dodecyl sulfate to a concentration of 1 mg/ml, and were then dispersed using a sonicator for 1 hour. Subsequently, agglomerated carbon nanotubes were separated from the resulting solution using a centrifugal separator to obtain a carbon nanotube-dispersed solution having high dispersivity.

The obtained carbon nanotube-dispersed solution was sprayed on the surface of a polyethylene terephthalate (PET) substrate heated to 60° C., and then dried at 60° C. to form a the carbon nanotube-dispersant mixing layer. The dried PET substrate sprayed with the carbon nanotube-dispersed solution was sufficiently washed with distilled water in order to remove the sodium dodecyl sulfate included in the carbon nanotube-dispersant mixing layer.

Subsequently, the PET substrate coated with the carbon nanotubes was impregnated with an epoxy methanol solution having a solid content of 1 wt % for 1 minute.

Subsequently, the PET substrate impregnated with the epoxy methanol solution was dried at 80° C. to form a polymer resin film (its thickness after drying is 0.001 μm from the top of the polymer substrate), thereby obtaining an electrode substrate including a carbon nanotube-polymer resin mixing layer containing no dispersant thereon.

### Example 2

An electrode substrate was manufactured using the same method as in Example 1, except that sodium dodecyl benzenesulfonate was used instead of sodium dodecyl sulfate at the time of preparing a carbon nanotube-dispersed solution.

### Example 3

An electrode substrate was manufactured using the same method as in Example 1, except that a polymer substrate coated with carbon nanotubes was impregnated with a polyurethane methanol solution having a solid content of 1 wt % for 1 minute using polyurethane as a polymer resin for impregnating the polymer substrate.

### Example 4

An electrode substrate was manufactured using the same method as in Example 1, except that a polymer substrate coated with carbon nanotubes was impregnated with an aqueous polyvinyl pyrrolidone solution having a solid content of 1 wt % for 1 minute using polyvinyl pyrrolidone (PVP) as a polymer resin for impregnating the polymer substrate.

### Example 5

An electrode substrate was manufactured using the same method as in Example 1, except that a polymer resin solution having a solid content of 0.1 wt % was used.

### Example 6

An electrode substrate was manufactured using the same method as in Example 1, except that a polymer substrate coated with carbon nanotubes was impregnated with a polymer resin solution for 10 minutes.

### Comparative Example 1

An electrode substrate was manufactured using the same method as in Example 1, except that a process of impregnating a polymer substrate coated with carbon nanotubes with a polymer resin solution was omitted.

The physical properties of the electrode substrates obtained from Examples 1 to 6 and Comparative Example 1 were evaluated as follows. The results thereof are given in Table 1 below.

(1) Optical Properties

The UV transmissivity of the electrode substrates was measured using a UV spectrometer (Cary 100, manufactured by Variant Corp.).

Here, the transmissivity (referred to as ‘transmissivity before impregnation’) of the electrode substrate including a the carbon nanotube-dispersant mixing layer from which the low-molecular-weight dispersant was removed before the electrode substrate is impregnated with a polymer resin solution, and the transmissivity (referred to as ‘transmissivity after impregnation’) of the finally obtained electrode substrate were measured.

(2) Surface Resistance

The surface resistance values of the electrode substrates was measured ten times using a high resistance meter (Hiresta-UP MCT-HT450, manufactured by Mitsubishi Chemical Corp.) having a measuring range of 10×10⁵˜10×10¹⁵ and a low resistance meter (CMT-SR 2000N, manufactured by Advanced Instrument Technology Corporation, 4-Point Probe System) having a measuring range of 10×10⁻³˜10×10⁵, and then the average value thereof was calculated.

Here, the surface resistance (referred to as ‘surface resistance before impregnation’) of the electrode substrate including the carbon nanotube-dispersant mixing layer from which the low-molecular-weight dispersant was removed before the electrode substrate is impregnated with a polymer resin solution, and the surface resistance (referred to as ‘ surface resistance after impregnation’) of the finally obtained electrode substrate were measured.

(3) Adhesion Test

The adhesion between a carbon nanotube-polymer resin mixing layer and a polymer substrate was measured using tape (ASTM D 3359-02). Concretely, the polymer substrate coated with carbon nanotubes was divided into 25 parts (5×5), and then tape was attached thereto and then detached therefrom at once. Then, the surface resistance of each of the parts was measured. When the ratio of the parts in which surface resistance change was observed is 0%, it is represented by 5B, when the ratio thereof is 5% or less, it is represented by 4B, when the ratio thereof is 5˜15%, it is represented by 3B, when the ratio thereof is 15˜35%, it is represented by 2B, when the ratio thereof is 35˜65%, it is represented by 1B, and when the ratio thereof is 65% or more, it is represented by 0B.

TABLE 1

| | | | | Surface resistance | | |
|---|---|---|---|---|---|---|
| | | | | (Ω/Sq) | | |
| | | Transmissivity (550 nm, %) | | surface | surface | |
| | Total | transmissivity | transmissivity | resistance | resistance | |
| | thickness | before | after | before | after | Adhesion |
| | (μm) | pregnation | pregnation | pregnation | pregnation | test |
| Exp. | 100 | 87 | 86.9 | 255 | 306 | 5B |
| 1 | | | | | | |
| Exp. | 100 | 88 | 88 | 320 | 374 | 5B |
| 2 | | | | | | |
| Exp. | 100 | 87.3 | 87 | 260 | 315 | 5B |
| 3 | | | | | | |
| Exp. | 100 | 87.5 | 87 | 279 | 332 | 5B |
| 4 | | | | | | |
| Exp. | 100 | 87.6 | 86.8 | 283 | 398 | 5B |
| 5 | | | | | | |
| Exp. | 100 | 88.1 | 87.9 | 326 | 375 | 5B |
| 6 | | | | | | |
| Comp. | 100 | 88.7 | — | 350 | — | 4B |
| Exp. | | | | | | |
| 1 | | | | | | |

From the results of Table 1 above, it can be seen that the carbon nanotube-polymer resin mixing layer is strongly attached to the polymer substrate. Further, it can be seen that the kind of a polymer resin for impregnation does not greatly influence transmissivity or surface resistance, and that as the solid content of a polymer resin solution for impregnation is increased, the carbon nanotube layer is thickly coated with the polymer resin, thus decreasing surface resistance.

As described above, according to the electrode substrate manufacturing method of the present invention, an electrode substrate including a carbon nanotube layer containing no dispersant and strongly coated with carbon nanotubes can be manufactured. Further, the present invention provides a method of manufacturing an electrode substrate regardless of the kind of binder.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing an electrode substrate, comprising the steps of:
applying a carbon nanotube-dispersed solution containing a low-molecular-weight dispersant onto a polymer substrate to form a the carbon nanotube-dispersant mixing layer;
washing the carbon nanotube-dispersant mixing layer to remove the low-molecular-weight dispersant;
impregnating the polymer substrate including the carbon nanotube-dispersant mixing layer from which the low-molecular-weight dispersant was removed with a polymer resin solution; and
taking out the polymer substrate from the polymer resin solution and then drying the polymer substrate.

2. The method according to claim 1, wherein the low-molecular-weight dispersant includes one or more selected from sodium dodecyl sulfate, lithium dodecyl sulfate, sodium dodecyl benzenesulfonate, sodium dodecyl sulfonate, dodecyltrimethylammonium bromide, and cetyltrimethylammonium bromide.

3. The method according to claim 1, wherein the carbon nanotube is selected from single-wall carbon nanotubes, double-wall carbon nanotubes, and multi-wall carbon nanotubes.

4. The method according to claim 1, wherein the polymer substrate is made of any one selected from polyimide, polyether sulfone, polyether ether ketone, polyethylene terephthalate, polybutylene terephthalate, polycarbonate, polyacrylate, and polyurethane.

5. The method according to claim 1, wherein, in the step of forming the carbon nanotube-dispersant mixing layer on the polymer substrate, the polymer substrate is coated with the carbon nanotube-dispersed solution containing the low-molecular-weight dispersant while it is heated to 60˜100° C.

6. The method according to claim 1, wherein the polymer resin constituting the polymer resin solution for impregnating the polymer substrate is selected from polyimide, polyether sulfone, polyether ether ketone, polyethylene terephthalate, polybutylene terephthalate, polycarbonate, polyacrylate, polyvinyl pyrrolidone, epoxy, and polyurethane.

7. The method according to claim 1, wherein the polymer resin constituting the polymer resin solution for impregnating the polymer substrate is a photocurable resin or a thermocurable resin.

8. The method according to claim 1, wherein the polymer resin solution for impregnating the polymer substrate includes at least one solvent selected from water, alcohol, acetone, ether, acetate, and toluene.

9. The method according to claim 1, wherein the polymer resin solution for impregnating the polymer substrate has a solid content of 0.01˜5 wt %.

10. The method according to claim 1, wherein the step of drying the polymer substrate is performed at a temperature of 10˜400° C. for 1 minutes ˜3 hours.

11. The method according to claim 1, wherein the step of drying the polymer substrate is performed such that a film formed on the polymer substrate by the polymer resin solution after the drying has a thickness of 0.001˜0.1 μm from the top of the polymer substrate.

12. The method according to claim 1, further comprising the step of: curing the dried polymer substrate after the step of drying the polymer substrate.

13. An electrode substrate manufactured by the method of any one of claims 1 to 12, wherein the electrode substrate is formed of a polymer resin substrate including a carbon nanotube-dispersed layer containing no dispersant thereon.
